(19) United States
(12) Patent Application Publication
(10) Pub. No.: US 2025/0283247 A1
(43) Pub. Date: Sep. 11, 2025

(54) SEED UNIT AND APPARATUS FOR GROWING A BULK SIC SINGLE CRYSTAL

(71) Applicant: SiCrystal GmbH, Nürnberg (DE)

(72) Inventors: Philipp SCHUH, Nürnberg (DE); Ralf MÜLLER, Nürnberg (DE); Matthias STOCKMEIER, Nürnberg (DE); Michael VOGEL, Nürnberg (DE); Bernhard ECKER, Nürnberg (DE)

(21) Appl. No.: 19/075,853

(22) Filed: Mar. 11, 2025

(30) Foreign Application Priority Data
Mar. 11, 2024 (EP) 24162679.5

(51) Int. Cl. C30B 23/02; C30B 29/36; C30B 35/00

(52) U.S. Cl. CPC C30B 23/025; C30B 29/36; C30B 35/002

(57) ABSTRACT

A seed unit for growing a bulk SiC single crystal has a wafer-like single crystalline SiC seed crystal with a growth surface arranged on a wafer front side for growing the bulk SiC single crystal to be grown. The SiC seed crystal has a crystal longitudinal mid-axis extending in an axial direction. A radial direction is oriented perpendicular to the axial direction. The seed unit also has a rear side layer component arranged on a wafer rear side of the SiC seed crystal, the structure of which changes starting from the crystal longitudinal mid-axis in the radial direction, and so a radial temperature gradient is adjusted during the growth of the bulk SiC single crystal within the SiC seed crystal.

### CROSS-REFERENCE TO RELATED APPLICATION

This application claims the priority, under 35 U.S.C. § 119, of European Patent Application EP 24 162 679.5, filed Mar. 11, 2024; the prior application is herewith incorporated by reference in its entirety.

### FIELD AND BACKGROUND OF THE INVENTION

The invention relates to a seed unit for growing a bulk SiC single crystal and an apparatus for growing a bulk SiC single crystal.

By reason of its excellent physical, chemical, electrical and optical properties, the semiconductor material silicon carbide (SiC) is also used, inter alia, as a starting material for power-switching semiconductor components, for high-frequency components and for special light-emitting semiconductor components. These components require SiC substrates (═SiC wafers) with the largest possible substrate diameter and of the highest possible quality. These are based on high-value bulk SiC single crystals.

Such bulk SiC single crystals are generally produced by means of physical vapor transport (PVT), e.g. by means of a sublimation method, as described in U.S. Pat. No. 8,865,324 B2. In that case, a single crystalline SiC wafer as an SiC seed crystal is introduced into a growth crucible together with a suitable source material. Under controlled temperature, pressure and gas conditions, the source material is sublimated. The gaseous species (═SiC, Si2C, SiC2) are transported to the SiC seed crystal by reason of an axial temperature gradient and at this location they are deposited on the SiC seed crystal from the SiC growth gas phase, whereby the bulk SiC single crystal grows.

From these bulk SiC single crystals, the wafer-like single crystalline SiC substrates are cut, e.g. by means of a wire saw, which are then, after an—in particular—multi-stage polishing treatment of their surface as part of the component manufacture, provided with at least one epitaxial layer also consisting in particular of SiC. Defects are generally passed on from the SiC substrate into the applied epitaxial layer and therefore lead to an impairment of the component properties. The quality of the components thus essentially depends on that of the grown bulk SiC single crystal and the SiC substrates obtained therefrom.

The geometry of the SiC substrate used is of great significance for the production of the epitaxial layers of the components. Thus, in an epitaxial reactor good thermal coupling, which is very important for homogeneous and high-quality epitaxial layer growth, is essentially achieved only in the case of SiC substrates which have no appreciable bowing. In contrast, SiC substrates with poor geometric properties, i.e., in particular with an excessive amount of bow and/or warp, inevitably lead to poorer quality and/or lower yield from the epitaxial process.

During the growth of the bulk SiC single crystal, the axial temperature gradient is decisively responsible for the material transport from the source material to the SiC seed crystal. On the one hand, it should be so high that it results in economically beneficial growth speeds but, on the other hand, it should not be so high that thermal stresses form to an increased extent in the crystal volume which result in the above-described problems in the SiC substrates produced from the bulk SiC single crystal. Owing to the axial temperature gradient prevailing in the growth crucible, a temperature difference between the warmer wafer rear side of the SiC seed crystal and the colder crucible region behind the SiC seed crystal is also produced on the rear side of the SiC seed crystal. In order to avoid vaporization of material from the wafer rear side of the SiC seed crystal to the rear and the associated defect formation in the bulk SiC single crystal growing on the wafer front side of the SiC seed crystal, rear side passivation is performed on the SiC seed crystal.

For instance, Chinese document CN 116121855 A describes that the SiC seed crystal is provided on its wafer rear side with a multi-layer protective layer consisting of carbon, in particular graphite.

United States published patent application US 2011/0229719 A1 describes that the SiC seed crystal is provided on its wafer rear side with a single-layer or multi-layer protective layer consisting of hard carbon, diamond-like carbon, diamond, tantalum or tantalum carbide in order to avoid material vaporization. US 2011/0229719 A1 also states that the SiC seed crystal possibly provided with a rear side protective layer is fastened to a crucible cover of the crucible used for growth either by means of an adhesive layer or by means of a mechanical holder.

Chinese document CN 218860954 U describes another approach in which the temperature within the SiC seed crystal is rendered uniform. Temperature differences and internal stresses, resulting therefrom, in the SiC seed crystal should thus be reduced. For this purpose, a multi-part thermal insulation which contains a displaceable adaptation element, is disposed on the rear side of the SiC seed crystal. Displacement of said adaptation element means that a cavity also provided on the rear side of the SiC seed crystal can be adapted in its dimensions to the respective (thermal) conditions. However, this construction is complex and therefore also expensive.

Chinese document CN 218175203 U describes a multi-part additional heating arrangement arranged on the rear side of the SiC seed crystal, the single parts of which can be displaced in order to be able to change the temperature field in a targeted manner even during the growing process. Even this structure is complex and expensive.

### SUMMARY OF THE INVENTION

The object of the invention is to provide a seed unit and an apparatus of the type mentioned in the introductory part, which allows the temperature field in the SiC seed crystal to be influenced in a simpler and better manner compared with the known prior art approaches.

With the above and other objects in view there is provided, in accordance with the invention, a seed unit for growing a bulk SiC single crystal, the seed unit comprising:
a) a wafer-shaped single crystalline SiC seed crystal having a growth surface on a wafer front side for growing the bulk SiC single crystal;
   a1) said SiC seed crystal having a crystal longitudinal mid-axis extending in an axial direction, and a radial direction oriented perpendicular to the axial direction;
and
b) a rear side layer component arranged on a wafer rear side of said SiC seed crystal;
   b1) a structure of said rear side layer component varying from the crystal longitudinal mid-axis outward in the radial direction, thus adjusting a radial temperature gradient within said SiC seed crystal during a growth of the bulk SiC single crystal.

In other words, the objects of the invention are achieved with a seed unit that has a wafer-like single crystalline silicon carbide (SiC) seed crystal having a growth surface arranged on a wafer front side for growing the bulk SiC single crystal to be grown, wherein the SiC seed crystal has a crystal longitudinal mid-axis extending in an axial direction, and a radial direction is oriented perpendicular to the axial direction, and a rear side layer component arranged on a wafer rear side of the SiC seed crystal, the structure of which changes in the radial direction starting from the crystal longitudinal mid-axis, and so a radial temperature gradient is produced within the SiC seed crystal during the growth of the bulk SiC single crystal.

The seed unit may also be referred to as a seed system.

The wafer-shaped or wafer-like SiC seed crystal has, in particular, a substantially cylindrical geometry. A peripheral edge surface of the SiC seed crystal has, in particular, substantially the shape of a cylindrical outer surface.

In particular, the rear side layer component covers the SiC seed crystal completely. It can preferably consist of a single layer or of a plurality of single layers. The term “structure of the rear side layer component” is to be understood here to mean in particular the geometric dimension of the rear side layer component and/or the material composition of the rear side layer component.

During its growth, the bulk SiC single crystal grows in the axial direction on the SiC seed crystal and has the same crystal longitudinal mid-axis as the SiC seed crystal or the seed unit. In this case, “axial” is to be understood to mean a direction parallel to, or along, the, in particular central crystal longitudinal mid-axis, “radial” is to be understood to mean a direction perpendicular thereto and “tangential” is to be understood to mean a peripheral direction extending around the crystal longitudinal mid-axis.

It has been recognized that the side and spatial distribution of the temperature differences or the temperature gradients in the growth region inter alia directly influence the growth rate, the phase boundary form and the thermal stresses in the growing bulk SiC single crystal. The stress distribution in the bulk SiC single crystal influences, for its part, the dislocation balance and also the bowing which the wafer-like SiC substrates, produced from the bulk SiC single crystal, subsequently have during the further process steps of the component production. The three-dimensional temperature field can be divided, in order to consider its effects, into an axial component (preferably axial temperature gradient) in the direction of the crystal longitudinal mid-axis and a radial component (preferably radial temperature gradient) perpendicular to the crystal longitudinal mid-axis or parallel to the particularly flat growth surface of the SiC seed crystal. Both components have an influence on the achievable crystal quality and are therefore to be taken into consideration.

For instance, the radial temperature gradient influences the form of the phase boundary and thus the surface of the growing bulk SiC single crystal. Ideally, the phase boundary is curved in a slightly convex manner so that disruptions in the edge region do not migrate inwards, but is not so convex that excessive stresses can be built up in the bulk SiC single crystal owing to an excessive curvature. Stresses in the bulk SiC single crystal result in the formation primarily of basal plane dislocations (BPD) which adversely influence the long-term stability of the electronic components which are produced from the SiC substrates obtained from the bulk SiC single crystal. Moreover, excessive stresses result in bowing of the SiC substrate upon further production, which results in a reduction in the yield of usable components.

It has also been recognized that optimized control of the complete heat flow from an axial end side of the growth crucible to the opposite other axial end side of the growth crucible, i.e., from the SiC source material through the SiC seed crystal to the crucible cover, can improve the temperature profile of the grown bulk SiC single crystal such that stresses are reduced and consequently the density of the basal plane dislocations are minimized. Also, SiC substrates having considerably lower bowing can be obtained from bulk SiC single crystals which are produced with this improved temperature profile, which results in an increased yield for the components subsequently produced thereon. The improved temperature profile is based substantially on the fact that a rear side layer component is provided on the wafer rear side of the SiC seed crystal, by means of which the heat transport from the bulk SiC single crystal growing on the wafer front side can be controlled. Owing to the rear side layer component, the axial temperature gradient and the radial temperature gradient can be largely separate and in particular also adjusted in a largely mutually independent manner. For instance, the radial temperature gradient can be influenced for example by the radial variation in the rear side layer component, without the axial temperature gradient being significantly altered. The rear side layer component can also preferably be used, besides for adjusting the radial temperature gradient, for rear side passivation, so that no material is vaporized from the wafer rear side of the SiC seed crystal. In this respect, it has an advantageous double function and is then in particular also a rear side-passivating protective layer.

An important aspect for the growth of a bulk SiC single crystal by means of the seed unit is the regulation of the temperature flow from the warmest to the coldest point of the growth apparatus. The warmest point is in the region of the SiC source material (in powder or solid form) introduced into the growth crucible in an SiC storage area and the coldest point is on an axial end side of the growth crucible opposite the SiC storage area, i.e., in particular on an axial end side-crucible cover which is arranged on the side of the seed unit facing away from the SiC storage area. After achieving the corresponding combination of temperature and pressure, a targeted material transport takes place owing to the adjustment of a corresponding temperature difference between the SiC seed crystal of the seed unit and the SiC source material, and the crystal growth begins. The phase boundary form (=growth boundary surface) of the growing bulk SiC single crystal depends primarily also on the heat dissipation through the seed unit in the direction of the crucible cover. This heat dissipation is advantageously influenced by the rear side layer component with a radially varying structure in the desired manner.

The physical principles forming the basis of heat transport are Fourier's Law (1):

$$Q = λ * A * \frac{T 1 - T 2}{d} , \qquad ( 1 )$$

where Q is the heat conduction transferred by heat conduction, T1 is the temperature of the warmer surface, T2 is the temperature of the cooler surface, A is the area through which heat flows, λ is the thermal conductivity (=a temperature-dependent material variable) and d is the thickness of the body between the colder and warmer surface, and the Stefan-Boltzmann Law (2):

$$Q = ε * σ * A * {T}^{4} , \qquad ( 2 )$$

where Q is the radiant power emitted by a body, ε is the emissivity of the body, σ is the Stefan-Boltzmann constant, A is the area of the body and T is the absolute temperature. Since SiC growth occurs above 2000 K, the Stefan-Boltzmann Law prevails for the production of the bulk SiC single crystal, said Law describing the heat transport via radiation, compared to the mechanism of heat conduction depicted by Fourier's Law.

The seed unit in accordance with the invention is preferably based on a locally defined combination of the two heat transport mechanisms, which favors homogenization or optimized adjustment of the local temperature differences. As a result, a very good phase boundary form of the growing bulk SiC single crystal can be generated. Furthermore, the internal stresses in the crystal microstructure and the defect density can be greatly reduced thereby. In particular, a good bulk SiC single crystal on the one hand has only a very slightly curved phase boundary which results in greatly reduced stresses within the crystal microstructure. In particular, on the other hand, a slightly convex curvature is desired in order to prevent defects, which occur in the edge region of the growing bulk SiC single crystal, from penetrating into the high-quality inner region which is particularly important for the further processing for component production. In order to achieve this, the seed unit in accordance with the invention has the in particular single- or multi-layered rear side layer component with a radially varying structure, the single layers of which can have different chemical and/or physical properties with a radially constant or radially variable thickness. As a result, the heat transport by radiation and heat conduction is adjusted such that virtually ideal values for the radial and preferably also for the axial temperature gradient are achieved. Cavities arranged on the rear side of the SiC seed crystal can also favor the described effect. These measures can be used individually or also in any combination with each other.

Previous rear side coatings of SiC seed crystals had the function of avoiding vaporization of material rearwards and the associated defect formation, but without having a targeted influence on the temperature distribution or the temperature gradients in the SiC seed crystal and in other regions of the growth crucible used for growing a bulk SiC single crystal.

Moreover, the temperature field is adjusted during the growth of a bulk SiC single crystal hitherto via geometric measures on the growth crucible and/or on the thermal insulation surrounding the growth crucible. However, as a result the axial temperature gradient and the radial temperature gradient are almost always coupled and practically cannot be adjusted separately from each other.

The seed unit in accordance with the invention, in which the radial temperature gradient can be adjusted by way of a suitable modification on the wafer rear side of the SiC seed crystal, namely by the placement there of the rear side layer component with its structure varying in the radial direction, makes it possible to optimize the temperature gradients in the radial and axial direction in a targeted manner and also substantially separate from each other, without exerting another undesired influence on the other conditions within the growth crucible used for growing a bulk SiC single crystal. In an advantageous manner, this modification on the wafer rear side of the SiC seed crystal does not require a bulky expansion conversion on the growth crucible. It is rather the case that the growth crucible remains as compact as before. Likewise, other variation options for optimizing the overall structure of the growth apparatus are preserved. Moreover, by virtue of the fact that the rear side layer component influencing the temperature gradient is arranged on, in particular immediately or directly adjacent to, the wafer rear side of the SiC seed crystal, the temperature gradient is adjusted in the closest proximity to the bulk SiC single crystal growing on the SiC seed crystal during growth. The thermal influence is thus very direct and efficient.

The seed unit thus permits, owing to the improved targeted influencing of the temperature field during the growth process, a massive reduction in the internal mechanical stresses and in the dislocations in the grown bulk SiC single crystal. This has a positive effect on the quality and yield of the subsequent process steps. Moreover, the seed unit permits the design of very compact, and very flexibly usable, growth apparatuses.

Advantageous embodiments of the seed unit in accordance with the invention are apparent, inter alia, from the features recited in the dependent claims.

An embodiment in which the rear side layer component consists of a single layer is favorable. The rear side layer component is then designed in particular with one layer. As a result, a particularly simple and cost-effective design is achieved. Preferably, the single layer has an axial layer thickness, i.e., a layer thickness measured in particular in the axial direction, between 0.5 μm and 10 μm, in particular between 1 μm and 5 μm. In the case of a layer thickness varying e.g. in the radial direction, this layer thickness refers in particular to the maximum thickness or expansion in the axial direction.

According to a further favorable embodiment, the rear side layer component consists of a plurality of single layers. The rear side layer component is then designed in particular with multiple layers. As a result, a design which can be adapted very precisely to the respective application is achieved. Preferably, at least some of the plurality of single layers are arranged axially one above another and/or radially one next to another. Preferably, an axial overall layer thickness of all the single layers is between 0.5 μm and 20 μm, in particular between 1 μm and 10 μm. In particular, all the single layers considered together have a common axial overall layer thickness. In the case of an overall layer thickness varying e.g. in the radial direction, this overall layer thickness refers in particular to the maximum thickness or expansion in the axial direction. Preferably, the single layers have at least in part a mutually different layer material. In particular, they consist at least in part of a mutually different layer material.

According to a further favorable embodiment, each single layer of the rear side layer component consists of a layer material which is a material from the group of carbon and a carbide or at least comprises a material of this group. In particular, the carbide is a metal carbide.

According to a further favorable embodiment, the rear side layer component has an axial component thickness which increases starting from the crystal longitudinal mid-axis in the radial direction. In particular, the axial component thickness increases continuously or in discrete steps. In particular, the axial component thickness increases in the radial direction starting from the crystal longitudinal mid-axis as far as a lateral edge, e.g. as far as a peripheral edge, of the rear side layer component by a factor of 1.5 to 20, preferably by a factor of 1.75 to 15 and preferably by a factor of 2 or a factor of 5 or a factor of 10.

According to a further favorable embodiment, the rear side layer component lies directly on the wafer rear side of the SiC seed crystal. As a result, the thermal influence on the SiC seed crystal and on the bulk SiC single crystal growing thereon during the growth is very direct and efficient. In particular, the radial temperature gradient prevailing during the growth can be influenced and adjusted in a very effective manner.

According to a further favorable embodiment, the rear side layer component is formed with a layer cavity. The layer cavity is in particular embedded, preferably completely embedded. The layer cavity preferably has an axial expansion of up to 5 mm. The layer cavity also favors the influencing and adjusting of the radial temperature gradient prevailing during the crystal growth in the SiC seed crystal and in the bulk SiC single crystal growing thereon. A rear side layer component provided with a layer cavity has a maximum component thickness measured in particular in the axial direction of preferably between 2 mm and 15 mm, preferably between 3 mm and 10 mm.

With the above and other objects in view there is also provided, in accordance with the invention, an apparatus for growing a bulk silicon carbide (SiC) single crystal. The apparatus comprises:
a) a heatable growth crucible formed with an SiC storage area arranged in a first portion for receiving SiC source material, and with a crystal growth area arranged in a second portion of the growth crucible;
b) a seed unit as described above; and
c) a seed holder for holding the seed unit within the growth crucible so that at least the growth surface of the SiC seed crystal of the seed unit is arranged or exposed in the crystal growth area.

In other words, the apparatus in accordance with the invention has a heatable growth crucible with an SiC storage area arranged in a first portion for receiving SiC source material, and with a crystal growth area arranged in the second portion, a seed unit or one of its favorable embodiments according to the previous description, and a seed holder for holding the seed unit within the growth crucible, so that at least the growth surface of the SiC seed crystal of the seed unit is arranged in the crystal growth area.

The first portion and the second portion are each arranged in particular within the growth crucible and are preferably spaced apart from each other. Preferably, the first portion is adjacent to a first axial end side (e.g. lower) boundary wall of the growth crucible.

The apparatus in accordance with the invention and its embodiments offer substantially the same advantages as have already been described in conjunction with the seed unit in accordance with the invention and its embodiments.

Advantageous embodiments of the apparatus in accordance with the invention are apparent, inter alia, from the dependent apparatus claims.

An embodiment in which an in particular rear side apparatus cavity is arranged on a rear side of the seed unit facing away from the SiC storage area, said apparatus cavity having in particular an axial expansion of up to 5 mm, is favorable. The apparatus cavity is formed in particular by a free space between the rear side of the seed unit and a second axial end side (e.g. upper) boundary wall of the growth crucible, preferably a crucible cover.

Although the invention is illustrated and described herein as embodied in a seed unit and an apparatus for growing a bulk SiC single crystal, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a side view of a first exemplary embodiment of a seed unit for growing a bulk SiC single crystal;

FIG. 2 shows an exemplary embodiment of an apparatus for growing a bulk SiC single crystal with the seed unit according to FIG. 1; and

FIGS. 3 to 7 show further exemplary embodiments of seed units, each for growing a bulk SiC single crystal.

Mutually corresponding parts are provided with the same reference signs throughout the figures.

Details of the exemplary embodiments that are explained in more detail hereinafter may also be considered to constitute an invention in their own right or be part of inventive subject matter.

### DETAILED DESCRIPTION OF THE INVENTION

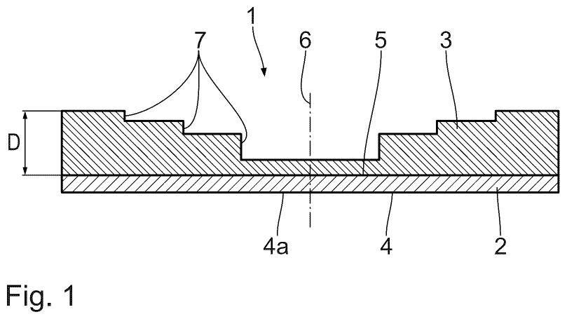

Referring now to the figures of the drawing in detail and first, in particular, to FIG. 1 thereof, there is shown an exemplary embodiment of a seed unit 1 for sublimation growth of a bulk SiC single crystal. The latter is not shown. The seed unit 1 has a wafer-like single crystalline SiC seed crystal 2 as well as a rear side layer component 3. The SiC seed crystal 2 has a wafer front side 4, on which a growth surface 4a is located for growing the bulk SiC single crystal to be grown, as well as a wafer rear side 5 opposite the wafer front side 4. On the wafer rear side 5, the SiC seed crystal 2 is directly coated with the rear side layer component 3. In this respect, the SiC seed crystal 2 and the rear side layer component 3 lie directly adjoining one another. The rear side layer component 3 completely covers the SiC seed crystal 2 on its wafer rear side 5.

The SiC seed crystal 2 and also the seed unit 1 on the whole have a central crystal longitudinal mid-axis 6. It coincides with the middle axis of symmetry of the, in particular, cylindrical geometry of the SiC seed crystal 2. A direction along the crystal longitudinal mid-axis 6 or parallel thereto is referred to as axial herein. A direction perpendicular to the crystal longitudinal mid-axis 6 is referred to as radial. A peripheral direction extending around the crystal longitudinal mid-axis 6 is tangential.

The rear side layer component 3 has a component thickness D measured in the axial direction which changes starting from the crystal longitudinal mid-axis 6 in the radial direction, i.e., towards the peripheral edge of the SiC seed crystal 2. This component thickness D increases in the radial direction, in the exemplified embodiment illustrated in FIG. 1 with a total of three discrete steps 7. The rear side layer component 3 has a geometric structure which changes starting from the crystal longitudinal mid-axis 6 in the radial direction. Owing to this radially varying structure, a radial temperature gradient is adjusted during the growth of a bulk SiC single crystal within the SiC seed crystal 2 (and in particular also in the area surrounding the SiC seed crystal 2 and in the growing bulk SiC single crystal), which results in the fact that internal mechanical stresses do not occur to an appreciable extent either in the SiC seed crystal 2 or in the growing bulk SiC single crystal. Preferably, this radial temperature gradient even contributes to reducing such internal stresses if they are already provided. As a result, ultimately a very defect-free bulk SiC single crystal is produced, from which also low-defect SiC substrates can be obtained for the production of high-quality components with a high yield.

The varying component thickness D of the rear side layer component 3 has values between 1 μm and 5 μm. In particular, the component thickness D increases starting from the center in the crystal longitudinal mid-axis 6 towards the peripheral edge, i.e., in the radial direction, by a factor of 5. At the peripheral edge, the component thickness D is at its maximum and measures at that location in particular 5 μm. The rear side layer component 3 is formed in one layer in the exemplified embodiment of FIG. 1. It thus contains only a single single layer. The rear side layer component consists of a metal carbide, in the illustrated exemplified embodiment of FIG. 1 of tantalum carbide (TaC). In alternative exemplified embodiments, not illustrated, the rear side layer component 3 can also consist of another layer material, e.g. of graphite, or another carbon material or of another carbide, in particular of a metal carbide with a high melting point metal, such as e.g. tungsten (W) or another refractory metal.

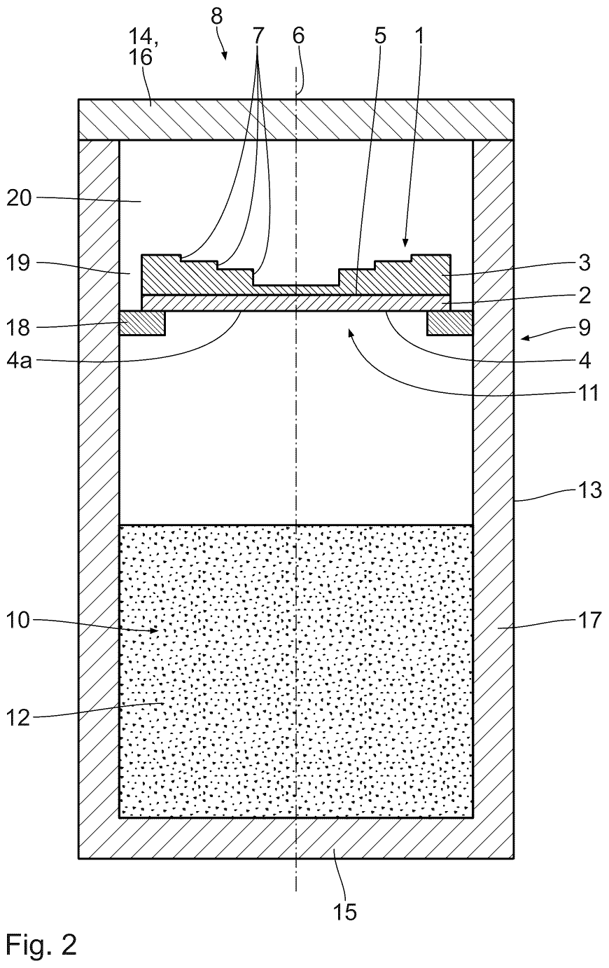

FIG. 2 illustrates an exemplified embodiment of a growth apparatus 8 for producing a bulk SiC single crystal (likewise not shown) by means of sublimation growth. The growth apparatus 8 contains a growth crucible 9 which contains an SiC storage area and a crystal growth area 11. The SiC storage area contains e.g. powdered SiC source material 12.

The growth crucible 9 has a crucible vessel 13 and a crucible cover 14. The growth crucible 9 has a first axial end wall 15, which is disposed adjacent to the SiC storage area, and a second axial end wall 16 opposite thereto, which is formed by the crucible cover 14. Furthermore, the growth crucible 9 has a peripheral wall 17 which, like the first axial end wall 15, is a component of the crucible vessel 13. The seed unit 1 of FIG. 1 is positioned in the growth crucible 9 by means of a seed holder 18 in such a way that the wafer front side 4 of the SiC seed crystal 2 is arranged with the growth surface 4a in the crystal growth area 11. In the illustrated exemplified embodiment, the wafer front side 4 of the SiC seed crystal 2 in the region of the peripheral edge lies loosely on the annular seed holder 18.

A peripheral gap 19 is provided between the inner side of the peripheral wall 17 and the seed unit 1.

The growth crucible 9 of FIG. 2 consists of an electrically and thermally conductive graphite crucible material. A thermal insulation, not shown in FIG. 2, is disposed around it. Furthermore, in order to heat the growth crucible 9 an, in particular, inductive heating device in the form of a heating coil is provided, also not shown. The growth crucible 9 is heated by means of this heating device to the high temperatures of over 2100° C. required for the growth.

The SiC growth gas phase in the crystal growth area 11 is fed through the SiC source material 12. The SiC growth gas phase contains at least gas components in the form of SiC, Si2C and SiC2 (═SiC gas species). The material transport from the SiC source material 12 to the growth surface 4a takes place along an axial temperature gradient which is set by means of the heating device and extends parallel to the crystal longitudinal mid-axis 6. A relatively high growth temperature of at least 2100° C., in particular of even at least 2200° C. or 2300° C. prevails at the growth surface 4a. At that location, gas components of the SiC growth gas phase are deposited, which leads to the growth of the bulk SiC single crystal. The temperature decreases within the growth crucible 9 from the SiC source material 12 in the axial direction to the crucible cover 14, whereby the axial temperature gradient mentioned above is created.

An apparatus cavity 20 is arranged on the rear side of the seed unit 1 facing away from the SiC storage area 10. It is located between the crucible cover 14 and the rear side layer component 3 of the seed unit 1. This apparatus cavity 20 additionally contributes to the radially varying structure of the rear side layer component 3 likewise for adjusting the above-mentioned temperature gradient. The apparatus cavity 20 is advantageous, but nevertheless is only optional. There are alternative exemplified embodiments without such an apparatus cavity 20.

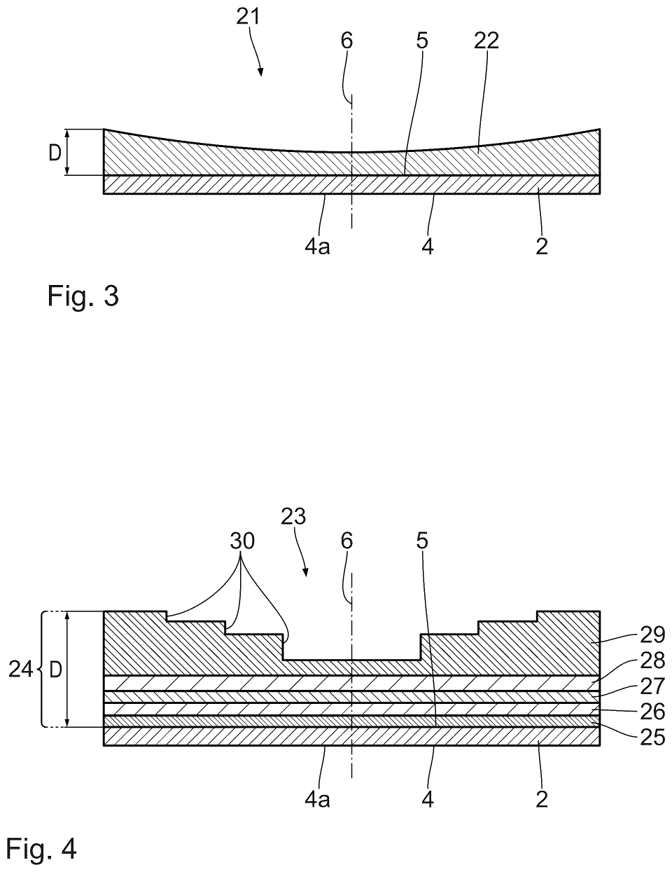

FIG. 3 illustrates a further exemplified embodiment of a seed unit 21. The seed unit 21 again contains the SiC seed crystal 2 with a wafer front side 4 and a wafer rear side 5. In contrast to the seed unit 1, the seed unit 21 has a differently designed rear side layer component 22. It is again designed in one layer, also completely covers the SiC seed crystal 2 and also its component thickness D increases starting from the crystal longitudinal mid-axis 6 in the radial direction as far as the peripheral edge, in the exemplified embodiment in particular by a factor of 2. In this case, the increase is not in steps but is continuous. At the peripheral edge, the component thickness D is at its maximum and measures at that location in particular 3 μm. In this respect, the rear side layer component 21 also has a geometric structure which changes starting from the crystal longitudinal mid-axis 6 in the radial direction, whereby, during the growth of the bulk SiC single crystal, a radial temperature gradient is adjusted again at least within the SiC seed crystal 2.

FIG. 4 illustrates a further exemplified embodiment of a seed unit 23 which comprises the SiC seed crystal 2 and a rear side layer component 24 which in this exemplified embodiment is designed with multiple layers. The rear side layer component 24 has a total of five single layers 25, 26, 27, 28 and 29. The first four single layers 25 to 28 applied directly onto the wafer rear side 5 of the SiC seed crystal 2 one above the other each have the form of a flat wafer and in this respect have the same axial expansion in particular at each location of the relevant single layer 25 to 28. In the illustrated exemplified embodiment, these four single layers 25 to 28 each consist of a thermally insulating material on a graphite basis and form an alternating layer system. The outermost single layer 29 is placed on this layer system of the four single layers 25 to 28 on the side facing away from the SiC seed crystal 2, which is similar in design to the rear side layer component 3 of FIG. 1. The single layer 29 has an axial expansion (=thickness of this single layer) which increases starting from the crystal longitudinal mid-axis 6 in the radial direction in three steps. In this respect, the outermost single layer 29 and thus the rear side layer component 24 have on the whole, again, a geometric structure which varies in the radial direction. As a result, the radial temperature gradient is adjusted. The outermost single layer 29 in the exemplified embodiment of FIG. 4 consists of a metal carbide, e.g. of tungsten carbide (WC). The rear side layer component 24 has an axial component thickness D which specifies the axial expansion of all the single layers 25 to 29 axially arranged one above the other, and which increases starting from the crystal longitudinal mid-axis 6 in the radial direction as far as the peripheral edge owing to the radial variation of the outermost single layer 29, in the exemplified embodiment the increase is in particular by a factor of 2. At the peripheral edge, the component thickness D is at its maximum and measures at that location in particular 10 μm.

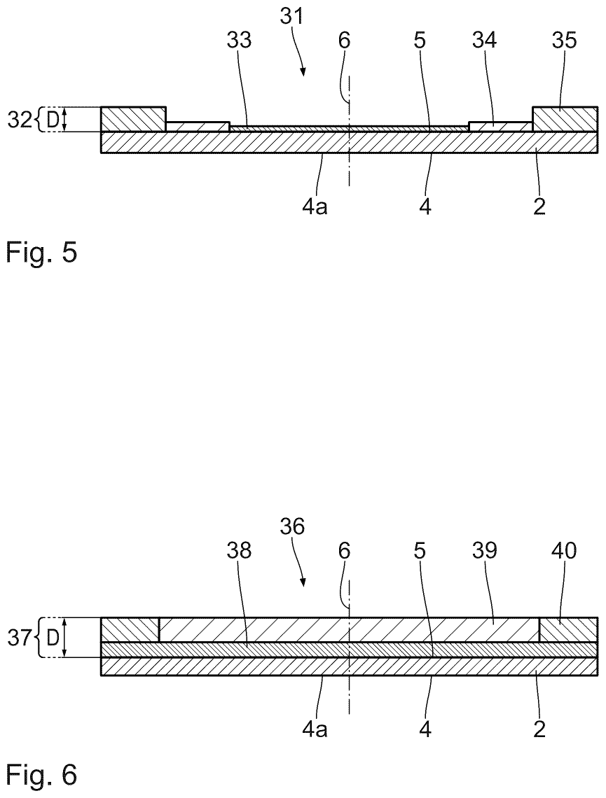

FIG. 5 illustrates a further exemplified embodiment of a seed unit 31 with the SiC seed crystal 2 and a further rear side layer component 32. The latter is designed in multiple layers, wherein, in contrast to the rear side layer component 24 of FIG. 4, in the exemplified embodiment of FIG. 5 the three single layers 33, 34 and 34 are not arranged axially one above the other but radially next to each other and concentrically to the crystal longitudinal mid-axis 6. The central single layer 33 is formed as a cylindrical full wafer and has the lowest (uniform) single layer thickness in the axial direction, in the exemplified embodiment in particular 1 μm. The middle single layer 34 directly radially adjoining the central single layer 33 is formed as an annular body and has a (uniform) single layer thickness which is greater than that of the inner single layer 33, in the exemplified embodiment in particular 2 μm. The outer single layer 35 directly adjoins the middle single layer 34 and has an even greater (uniform) single layer thickness, compared to said middle single layer, in the exemplified embodiment in particular 5 μm. The component thickness D of the rear side layer component 32 also increases starting from the crystal longitudinal mid-axis 6 in the radial direction as far as the peripheral edge, in the exemplified embodiment in particular by a factor of 5. For the rear side layer component 32, on the whole a structure is again produced, the geometry of which changes starting from the crystal longitudinal mid-axis 6 in the radial direction. In the exemplified embodiment of FIG. 5, the single layers 33, 34 and 35 each consist of a different thermally insulating layer material on a graphite basis.

FIG. 6 illustrates a further exemplified embodiment of a seed unit 36 with the SiC seed crystal 2 and a further rear side layer component 37. The rear side layer component 37 is also designed in multiple layers and is composed of a lower single layer 38 which contacts and covers the entire wafer rear side 5 of the SiC seed crystal 2, and a two-part upper layer with a wafer-like middle single layer 39 and an edge-side annular single layer 40 concentrically surrounding the middle single layer. The rear side layer component 37 has the same axial expansion at every point. The component thickness D is the same overall in this exemplified embodiment. It is e.g. 4 μm. However, in particular at least the two single layers 39 and 40 of the upper or outer layer each consist of a different layer material so that in this exemplified embodiment the structure of the rear side layer component 37 changes in terms of material composition starting from the crystal longitudinal mid-axis in the radial direction and as a result thereof also in this exemplified embodiment the desired adjustment of a radial temperature is achieved during the growth of the bulk SiC single crystal.

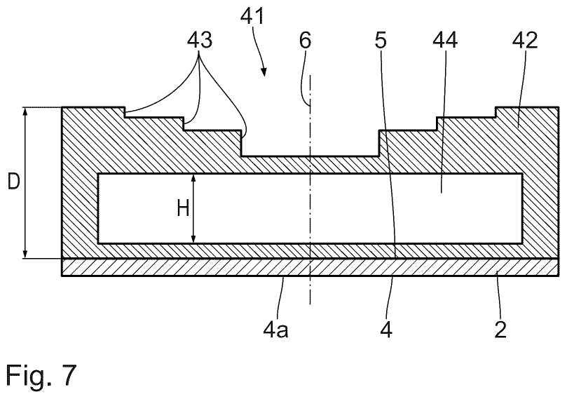

FIG. 7 illustrates a further exemplified embodiment of a seed unit 41 with the SiC seed crystal 2 and a further single-layer rear side layer component 42. The side of the rear side layer component 42 facing away from the wafer rear side 5 of the SiC seed crystal 2 has an uneven contour having three concentric steps 43 comparable to the rear side layer components 3 and 24. The component thickness D of the rear side layer component 42 thus also increases starting from the crystal longitudinal mid-axis 6 in the radial direction as far as the peripheral edge, in the exemplified embodiment in particular by a factor of 1.5. In the center, the component thickness D is e.g. 4 mm, at the peripheral edge—where it has its maximum axial expansion—it is e.g. 6 mm. In addition, in the interior of the rear side layer component 42 a layer cavity 44 is provided which has an axial cavity height H of e.g. 3 mm. The rear side layer component 42 has, owing to its rear side surface contour, a structure varying in the radial direction. Therefore and also owing to the layer cavity 44, the adjustment of a radial temperature gradient is effected during the growth of the bulk SiC single crystal.

The seed units 21, 23, 31, 36 and 41 can be used in the apparatus 8 of FIG. 2 instead of the seed unit 1 used there for growing a bulk SiC single crystal. All the seed units 1, 21, 23, 31, 36 and 41 are characterized in that they permit an in particular separate adjustment of the radial temperature gradient and the axial temperature gradient within the growth apparatus 8 and thus contribute to a particularly low-defect growth of the bulk SiC single crystal.

1. A seed unit for growing a bulk silicon carbide (SiC) single crystal, the seed unit comprising:
a) a wafer-shaped single crystalline SiC seed crystal having a growth surface on a wafer front side for growing the bulk SiC single crystal;
a1) said SiC seed crystal having a crystal longitudinal mid-axis extending in an axial direction, and a radial direction oriented perpendicular to the axial direction;
and
b) a rear side layer component arranged on a wafer rear side of said SiC seed crystal;
b1) a structure of said rear side layer component varying from the crystal longitudinal mid-axis outward in the radial direction, thus adjusting a radial temperature gradient within said SiC seed crystal during a growth of the bulk SiC single crystal.

2. The seed unit according to claim 1, wherein said rear side layer component consists of a single layer.

3. The seed unit according to claim 2, wherein said single layer has an axial layer thickness between 0.5 μm and 10 μm.

4. The seed unit according to claim 3, wherein said single layer thickness lies between 0.1 μm and 5 μm.

5. The seed unit according to claim 1, wherein said rear side layer component consists of a plurality of single layers.

6. The seed unit according to claim 5, wherein at least some of said plurality of single layers are arranged axially above one another and/or radially next to each other.

7. The seed unit according to claim 5, wherein an axial overall layer thickness of all of said single layers lies between 0.5 μm and 20 μm.

8. The seed unit according to claim 7, wherein the axial overall layer thickness of said single layers lies between 1 μm and 10 μm.

9. The seed unit according to claim 5, wherein said single layers at least in part have mutually different layer materials.

10. The seed unit according to claim 5, wherein each of said single layers of said rear side layer component consists of a layer material selected from the group consisting of carbon and a carbide or comprises at least one material selected from the group consisting of carbon and a carbide.

11. The seed unit according to claim 2, wherein said single layer of said rear side layer component consists of a layer material selected from the group consisting of carbon and a carbide or comprises at least one material selected from the group consisting of carbon and a carbide.

12. The seed unit according to claim 1, wherein said rear side layer component has an axial component thickness which increases from the crystal longitudinal mid-axis in the radial direction.

13. The seed unit according to claim 12, wherein the axial component thickness increases continuously or with discrete steps.

14. The seed unit according to claim 1, wherein said rear side layer component directly adjoins said wafer rear side of said SiC seed crystal.

15. The seed unit according to claim 1, wherein the rear side layer component is formed with a layer cavity.

16. The seed unit according to claim 15, wherein the layer cavity has an axial expansion in the axial direction of up to 5 mm.

17. An apparatus for growing a bulk silicon carbide (SiC) single crystal, the apparatus comprising:
a) a heatable growth crucible formed with an SiC storage area arranged in a first portion for receiving SiC source material, and with a crystal growth area arranged in a second portion of said growth crucible;
b) a seed unit according to claim 1; and
c) a seed holder for holding said seed unit within said growth crucible so that at least the growth surface of said SiC seed crystal of said seed unit is arranged in said crystal growth area.

18. The apparatus according to claim 17, wherein an apparatus cavity is arranged on a rear side of said seed unit facing away from said SiC storage area.

19. The apparatus according to claim 18, wherein said apparatus cavity has an axial expansion of up to 5 mm.
